(19) United States
(12) Patent Application Publication
(10) Pub. No.: US 2006/0125494 A1
(43) Pub. Date: Jun. 15, 2006

(54) Electromigration test device and electromigration test method

(76) Inventor: Jochen Von Hagen, Koberrnoor (DE)

Correspondence Address: BRINKS HOFER GILSON & LIONE;INFINEON, PO BOX 10395, CHICAGO, IL, 60610, US

(21) Appl. No.: 10/519,659

(22) PCT Filed: Jun. 25, 2003
(86) PCT No.: PCT/DE03/02112

§ 371 Date: Dec. 19, 2005

(30) Foreign Application Priority Data
Jun. 25, 2002 (DE) 102 28 284.6

(51) Int. Cl. G01R 27/08

(52) U.S. Cl. 324/722

(57) ABSTRACT

The invention relates to an electromigration test apparatus having a direct-current source 101 and an AC voltage source 102. Furthermore, it has a circuit 104 having a conductive structure 100, which is electrically coupled to the direct-current source 101 and the AC voltage source 102, and a measuring device for measuring an electrical parameter which is indicative of electromigration in the conductive structure. The AC voltage source 102 is set up in such a way that it exposes the conductive structure 100 to an alternating current, independently of a direct current, and thus heats the conductive structure 100 to a predetermined temperature.

The invention relates to an electromigration test apparatus and an electromigration test method.

With rising demands being made of microelectronic components, greater attention is increasingly being given to tests for determining interconnect reliability. One mechanism which can damage components is electromigration. Electromigration is understood to be the transport of material within an interconnect under the action of the electric current. The transport of material takes place in the direction of flow of the electrons. The latter entrain the lattice atoms of the interconnect material on account of the so-called electron wind that arises. This transport of material can lead to various instances of damage. One instance of damage is so-called voids, for example, i.e. gaps within the lattice structure, and interruptions developing therefrom in the interconnect. A further example is so-called extrusions, i.e. lateral outflows of interconnect material from the actual interconnect. These extrusions can lead to short circuits between adjacent interconnects and thus to the failure of the component. The magnitude of the electromigration is a parameter which determines the lifetime of the electronic component.

The intensity of the electromigration process depends principally on the material of the interconnect, the temperature and the electrical current density in the interconnect, the degree of electromigration increasing as the temperature rises and as the electrical current density rises. The direct-current component of the electrical current density is crucial for the intensity of the electromigration process. A symmetrical alternating current scarcely influences the electromigration intensity. Electromigration caused by a symmetrical alternating current occurs 100 to 1000 times more slowly than electromigration caused by means of a direct current [1]. It is apparent from this that, in the event of superposition of an alternating current and a direct current, the magnitude of the electromigration is dominated by the electrical current density caused by means of the direct current. This can clearly be explained by the fact that the so-called electron wind must have a preferred direction in order that it can effectively entrain the material of the conductive structure in one direction. However, a symmetrical alternating current does not have such a preferred direction of the electron wind.

For modern reliability tests, during the production of integrated electronic circuits, tests are carried out on special test structures. The test structures are generally fabricated together with the actual components on the same substrate and on the same materials as the components. The test structures are thus subject to the same fabrication processes and can be used to assess the electromigration strengths of similar interconnects in the end product.

In accordance with the prior art, a special test structure is used for every possible damage mechanism caused by electromigration on a conductive structure, which test structure is then subjected to an increased stress in the test by artificially influencing parameters which influence the electromigration, so that the electromigration is intensified. Consequently, statements about the electromigration strength can be obtained within a short time.

In order to investigate the magnitude of the electromigration, the test structures (e.g. metal interconnects) are sawn from the wafer and mounted in ceramic housings. The ceramic housings are placed onto circuit boards. The circuit boards are subsequently arranged in a measurement set-up and, having been introduced into suitable heating furnaces, are subjected to electromigration tests. For this purpose, the test structures are exposed to a constant direct current.

One instance of damage which can be caused by electromigration is, as mentioned above, by way of example, the formation of so-called voids, i.e. gaps within the lattice structure and interruptions developing therefrom in the conductive structure, e.g. interconnects of an integrated circuit. In order to investigate such damage, use is made e.g. of a simple interconnect with its corresponding connections. The interconnect is put under stress, i.e. elevated temperature and elevated current density. The time which elapses until the failure of the test structure is measured in this case. This time supplies a measure of the intensity of the electromigration processes to which a component succumbed. By means of the time until the failure of the structure and Black's equation, it is possible to calculate the average lifetime of the structure under normal operating conditions.

A further instance of damage which can be caused by electromigration is, as mentioned, by way of example, an occurrence of so-called extrusions, i.e. an outflow of material from the interconnect under the action of electromigration. The extrusions may lead to short circuits and thus to the failure of an electronic circuit situated on the wafer.

One disadvantage of the test apparatuses in accordance with the prior art is that the test structures, i.e. conductive structures whose susceptibility to electromigration is to be investigated, first have to be prepared for the test. The test structures are sawn out and subsequently mounted again in a test apparatus. These steps are both labour-intensive and time-consuming and thus also cost-intensive. Moreover, the circuit boards used for the test apparatus must also be heat-resistant. This means that the temperature can only be increased to about 400° C. since there are no circuit boards which withstand a higher temperature without damage. Even for these temperatures there are only few circuit boards which withstand this temperature for a relatively long time. Thus, temperatures of more than 350° C. cannot be handled industrially.

Furthermore, the stress, or to put it another way the loading which can be imposed on the test structure, is restricted by the limited temperature and, consequently, the tests require a longer time to be able to make a conclusive statement about the extent of the electromigration in the test structure.

A further disadvantage is the need for an external furnace for heating the circuit board and the test structure. The heating furnaces used are complicated and their use causes additional costs in carrying out the investigation of electromigration.

So-called self-heating test structures are also known in the prior art. These test structures exploit the fact that the test structures heat up by means of the direct current, serving as stress source for the test structure, owing to the nonreactive resistance of the conductive structure to be tested. As a result of this, an external heating furnace can be obviated in the case of a self-heating test structure.

However, these self-heating test structures have the disadvantage that in them two of the quantities which influence electromigration are coupled to one another. It is not possible to increase the electrical current density in the conductive structure independently of the temperature. Every increase in the electrical current density also leads to an increase in the temperature of the conductive test structure. This leads to a restriction of the parameter space of the quantities to be investigated, which restriction is unacceptable.

The effect of an asymmetrical current on electromigration is investigated in J. A. Maiz [2]. As a result, it is apparent that the equivalent direct current of an asymmetrical current is given by the average value of the current of the signal.

U.S. Pat. No. 4,739,258 discloses an electromigration test apparatus in which a number of integrated circuits each having a thin-film interconnect are implemented at the wafer level. The test apparatus is heated by means of an external heater and the change in the resistance of the thin-film interconnect is plotted against temperature.

The invention is based on the problem of providing a simple test apparatus by means of which the temperature can be regulated without an external furnace. However, the intention is for the test structure not to exhibit any undesirable coupling of the two quantities temperature and electrical current density, as occurs in a self-heating test structure in accordance with the prior art.

The problem is solved by means of an electromigration test apparatus and an electromigration test method having the features in accordance with the independent patent claims.

An electromigration test apparatus according to the invention has a direct-current source and an alternating-current source. Furthermore, the test apparatus has a circuit. The latter has at least one conductive structure to be tested, which is electrically conductively connected to the direct-current source and the alternating-current source. Furthermore, the test apparatus has a measuring device, which is set up in such a way that it detects an electrical parameter, which parameter is indicative of electromigration in the test structure. In the electromigration test arrangement, the AC voltage source is set up in such a way that it exposes the conductive structure to be tested to an alternating current, independently of a direct current of the direct-current source. By means of the alternating current generated by the AC voltage source, the conductive structure to be tested is heated to a predeterminable, preferably settable, temperature.

A method according to the invention for testing a conductive structure for electromigration has the following steps. A conductive structure to be tested is electrically coupled to an electrical circuit, which electrical circuit is electrically coupled to a direct-current source and an alternating-current source. In an additional step, the conductive structure to be tested is exposed to an electrical direct current, which direct current brings about the electromigration within the conductive structure to be tested. Furthermore, the method according to the invention exhibits heating of the conductive structure to be tested by means of an alternating current generated by the AC voltage source, the alternating current being independent of the direct current which causes the electromigration within the conductive structure to be tested. Furthermore, the method according to the invention has the step of detection of an electrical parameter, which parameter is indicative of the electromigration within the conductive structure to be tested.

The apparatus and the method provide a simple test apparatus by means of which the temperature is regulated without the use of an external furnace. The undesirable coupling of the two quantities temperature and electrical current density, as occurs in a self-heating test structure in accordance with the prior art, is avoided as a result. The preferably symmetrical electrical alternating current which serves for heating the conductive structure to be tested does not itself cause electromigration in the structure to be tested. With the test structure according to the invention, the temperature to which the structure to be tested is exposed can be increased to significantly more than 400° C. since only the electrically conductive structure to be investigated is heated in the case of the apparatus and the method. The circuit board itself is not exposed to an elevated temperature. This also obviates the problems and restrictions (e.g. heat resistance) which occur in the case of test structures in accordance with the prior art in the selection of the circuit boards.

A further advantage of the apparatus according to the invention compared with an apparatus in accordance with the prior art is that, by virtue of the fact that the temperature can be brought to higher values, the individual tests of the conductive structures to be tested can be carried out in a shorter time. The test apparatus according to the invention enables investigations of the electromigration in time periods in the minutes range, preferably in a time period of 10 minutes to 100 minutes. The brevity of the periods of time enables the tests to be carried out directly at the wafer level. This leads to a further cost saving, since the abovementioned extensive actions for preparing the conductive structure to be tested are obviated.

Preferred developments of the invention emerge from the dependent claims.

The electromigration test apparatus according to the invention is described in more detail below. Refinements of the electromigration test apparatus also apply to the method for testing a conductive structure for electromigration.

In the electromigration test apparatus according to the invention, the electrically conductive parameter is preferably an electrical resistance of the conductive structure to be tested.

The electromigration test apparatus according to the invention preferably furthermore has an evaluation unit for determining an electrical power. The evaluation unit preferably has a voltage measuring device and a current measuring device. The voltage measuring device and the current measuring device are introduced into the circuit in such a way that the current measuring device measures an electrical root-mean-square current flowing through the conductive structure to be tested, and that the voltage measuring device detects an electrical root-mean-square voltage across the conductive structure to be tested. The conductive structure to be tested preferably comprises aluminium, copper or an alloy of copper and aluminium or other electrically conductive materials such as gold or silver.

The test apparatus according to the invention furthermore preferably has a control device. The control device is set up in such a way that it controls and/or regulates the AC voltage source in such a way that the temperature of the conductive structure to be tested is set and kept constant at a predetermined level.

At least some of the components of the test apparatus according to the invention are preferably arranged on a semiconductor wafer.

The alternating-current source is preferably integrated in a pulse generator. The DC voltage source is preferably also integrated in the pulse generator. In other words, the pulse generator is preferably designed as an alternating-current source provided with an offset.

The AC voltage source is preferably set up in such a way that it generates an alternating current with a frequency of between 1 kHz and 200 kHz, particularly preferably with 5 kHz.

The electromigration test apparatus according to the invention furthermore preferably has, in addition, a heating furnace or heating plate, which is set up in such a way that it heats the conductive structure to be tested. This heating furnace can be used to set an offset temperature. The latter is preferably approximately 200° C. to 250° C.

An exemplary embodiment of the invention is illustrated in the figures and is explained in more detail below.

In the figures:

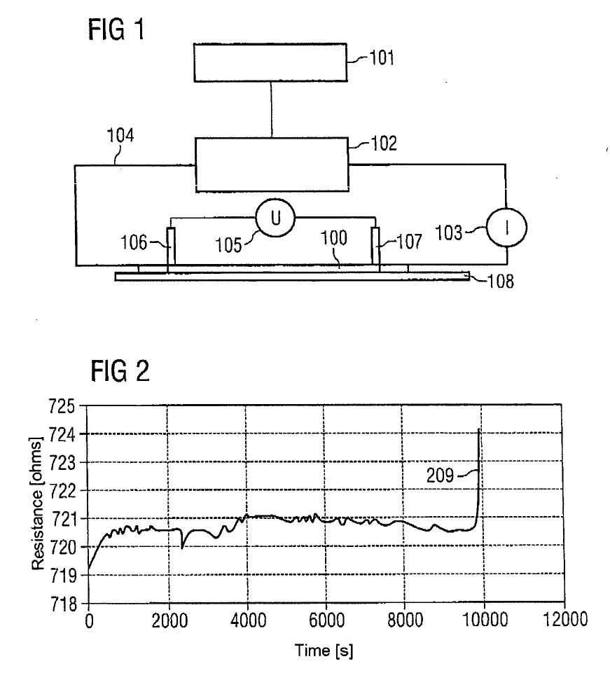

FIG. 1 shows an electromigration test apparatus in accordance with an exemplary embodiment of the invention;

FIG. 2 shows a measurement curve of a resistance of a conductive structure over time.

Referring to FIG. 1, an electromigration test apparatus in accordance with an exemplary embodiment of the invention is described in more detail.

The electromigration test apparatus has a wafer 108 with a conductive structure 100 to be tested. The conductive structure to be tested is composed of aluminium.

Furthermore, the test apparatus has a direct-current source 101. The direct-current source 101 is electrically conductively connected to the conductive structure 100 to be tested. The direct-current source 101 serves to put the conductive structure 100 under stress. In other words, the electrically conductive structure 100 is exposed, by means of an applied direct current of the direct-current source, to conditions which accelerate the electromigration in the conductive structure 100. This stress condition is an elevated electrical current density compared with normal operation of an electronic component.

Furthermore, the test apparatus has a pulse generator 102. The latter is connected between the direct-current source 101 and the conductive structure 100 to be tested. The pulse generator 102 superposes a symmetrical alternating current on the direct current, which serves as stress current. The symmetrical alternating current is used to heat the electrically conductive structure by means of a nonreactive resistance of the electrically conductive structure 100. Since the pulse generator provides a symmetrical alternating current, the electromigration is scarcely influenced by the electrical current density effected by the alternating current. The sole effect of the alternating current is to heat the conductive structure 100 to be tested. The temperature set in the exemplary embodiment is 262° C. In the exemplary embodiment, the temperature is determined by detecting the thermal resistance increase of the conductive structure. If appropriate, the magnitude of the alternating current is readjusted, thereby maintaining a constant temperature and thus constant stress conditions for the electrically conductive structure. The magnitude of the alternating current required for heating to this temperature is 23.3 mA. The frequency of the alternating current is 5 kHz. The direct current serving as stress current is 0.5 mA.

Furthermore, the test apparatus has a current measuring device 103. The current measuring device 103 is integrated in a circuit 104, which electrically conductively couples the conductive structure 100 to be tested, the direct-current source 101 and the pulse generator 102. The current measuring device 103 detects the root-mean-square current flowing through the conductive structure 100.

Furthermore, the electromigration test apparatus according to the invention has a voltage measuring device 105. The voltage measuring device 105 detects the electrical root-mean-square voltage which is dropped across the electrically conductive structure 100 between a first voltage tap 106 and a second voltage tap 107, of which one of the voltage taps is arranged in the start region and the other voltage tap is arranged in the end region of the conductive structure.

Furthermore, the electromigration test apparatus according to the invention has a computer (not shown). The computer reads in values detected by the voltage measuring device 105 and the current measuring device 104. By means of the detected values read in, the computer determines a resistance of the conductive structure 100 to be tested. Using the resistance thus determined, the temperature of the conductive structure to be tested (stress temperature) is also determined. Furthermore, the computer is set up in such a way that it readjusts the magnitude of the alternating current in such a way that the stress temperature is constant.

The conductive structure 100 to be tested is arranged directly at the wafer level of a semiconductor wafer.

FIG. 2 shows the temporal profile of the resistance of the electrically conductive structure 100 to be tested, which resistance is determined by means of the electromigration test apparatus according to the invention. The parameters for determining the resistance were an alternating current of 23.3 mA, which correspond to a temperature of 262° C. The stress current imposed is 0.5 mA. The test was carried out over a time period of about 10 000 s. An abrupt rise 209 in the resistance determined towards the end of the measurement period is clearly discernible.

At this point in time, the electromigration has caused damage to the electrically conductive structure to be tested, on account of which one or more voids bring about a drastic reduction of the conductive material in the line cross-section. The resistance rises abruptly as a result. A test for investigating the electromigration preferably lasts until a significant increase in the electrical resistance is registered.

To summarize, the invention provides an electromigration test apparatus which enables fast, simple and cost-effective testing of conductive structures that are to be tested for electromigration. On the one hand, the electromigration test apparatus according to the invention does not require an external heating furnace for heating the conductive structure to be tested. On the other hand, however, the embodiment according to the invention also does not exhibit the disadvantage of the self-heating test structures in accordance with the prior art, namely that the two parameters temperature and electrical current density, which influence the electromigration in the conductive structure to be tested, are coupled.

The following document is cited in this document:
[1] Electromigration under Time-Varying Current Stress, T. Jiang et al., Microelectronics Reliability 38(3) (1998) pp. 295-308
[2] Characterization of Electromigration under Bidirectional (BC) and Pulsed Unidirectional (PDC) Currents, J. A. Maiz, Reliability Physics Symposium, 27th Annual Proceedings, April 1989, pp. 220-228

1. An electromigration test apparatus having:
a direct-current source;
an AC voltage source;
a circuit having at least one conductive structure to be tested, which is electrically coupled to the direct-current source and the AC voltage source; and
a measuring device, which is set up in such a way that the measuring device detects an electrical parameter which is indicative of electromigration in the conductive structure to be tested;
the direct-current source being set up to expose the conductive structure to conditions which accelerate electromigration;
the AC voltage source being set up in such a way that the AC voltage source exposes the conductive structure to be tested to an alternating current, independently of a direct current of the direct-current source and thus heats the conductive structure to be tested to a predetermined temperature that can be set.

2. The apparatus according to claim 1, the electrical parameter being a resistance of the conductive structure to be tested.

3. The apparatus according to claim 1, which furthermore has an evaluation unit for determining an electrical power, the evaluation unit having a voltage measuring device and a current measuring device which are implemented in the circuit in such a way that, by means thereof, a root-mean-square current through the conductive structure to be tested and a root-mean-square voltage across the conductive structure to be tested can be detected.

4. The apparatus according to claim 1, a control device being provided, which is set up in such a way that the control device controls the AC voltage source in such a way that the temperature of the conductive structure to be tested can be kept constant.

5. The apparatus according to claim 1, the conductive structure to be tested being arranged on or in a semiconductor wafer.

6. The apparatus according to claim 1, the alternating-current source and the direct-current source being integrated in a pulse generator.

7. The apparatus according to claim 1, which furthermore has a heating furnace set up in such a way that the heating furnace heats the conductive structure to be tested.

8. A Method for testing a conductive structure for electromigration, having the following steps:
electrically coupling a conductive structure to be tested to an electrical circuit electrically coupled to a direct-current source and an alternating-current source;
supplying the conductive structure to be tested with a direct current which causes the electromigration within the conductive structure to be tested;
heating the conductive structure to be tested by means of the alternating current to a predetermined temperature which can be set, the alternating current being independent of a direct current, the direct current bringing about the electromigration within the conductive structure to be tested; and
detecting an electrical parameter which is indicative of the electromigration within the conductive structure to be tested.

9. The method according to claim 8, a resistance of the conductive structure to be tested being detected as the electrical parameter.

10. The method according to claim 8, in which, as further steps, a root-mean-square current in the conductive structure to be tested and a root-mean-square voltage across the conductive structure to be tested are detected and an electrical power is determined therefrom.

11. The method according to claim 8, the temperature of the conductive structure to be tested being regulated to a constant value by means of an evaluation unit.

12. The method according to claim 8, the conductive structure to be tested being formed on or in a semiconductor wafer.
